(19) United States
(12) Patent Application Publication
(10) Pub. No.: US 2015/0255253 A1
(43) Pub. Date: Sep. 10, 2015

(54) VACUUM CHAMBER ELEMENTS MADE OF ALUMINUM ALLOY

(71) Applicant: CONSTELLIUM FRANCE, Paris (FR)

(72) Inventors: Joost Michel Van Kappel, Suisse (CH); Cedric Gasqueres, Aix en Provence (FR); Kristin Ulla Pippig Schmid, Suisse (CH); Maria Belen Davo Gutierrez, Coublevie (FR)

(21) Appl. No.: 14/434,465

(22) PCT Filed: Oct. 15, 2013
(86) PCT No.: PCT/FR2013/000271

§ 371 Date: Apr. 9, 2015

Related U.S. Application Data
(60) Provisional application No. 61/728,021, filed on Nov. 19, 2012.

(30) Foreign Application Priority Data
Oct. 17, 2012 (FR) 12/02766

(51) Int. Cl. H01J 37/32; C25D 11/16; C22C 21/02; C22F 1/00; C22F 1/05; C22C 21/08; C25D 11/10; C25D 11/24

(52) U.S. Cl. CPC H01J 37/32467; C25D 11/10; C25D 11/16; C25D 11/24; H01J 37/32495; C22F 1/002; C22F 1/05; C22C 21/08; C22C 21/02

(57) ABSTRACT

The invention relates to a vacuum chamber element obtained by machining and surface treatment of a plate of thickness at least equal to 10 mm of aluminum alloy, composed as follows (as a percentage by weight), Si: 0.4-0.7; Mg: 0.4-0.7; Ti 0.01-<0.15, Fe<0.25; Cu<0.04; Mn<0.4; Cr 0.01-<0.1; Zn<0.04; other elements <0.05 each and <0.15 in total, the rest aluminum. The invention also relates to a manufacturing method for a vacuum chamber element wherein successively a plate with a thickness of at least 10 mm of aluminum alloy of series 5XXX or series 6XXX is provided, said plate is machined to a vacuum chamber element, said element is degreased and/or pickled, it is anodized at a temperature of between 10 and 30° C. with a solution comprising 100 to 300 g/l of sulfuric acid and 10 to 30 g/l of oxalic acid and 5 to 30 g/l of at least one polyol, optionally the anodized product is hydrated in deionized water at a temperature of at least 98° C. preferably for a period of at least about 1 h. Products according to the invention have an improved property homogeneity and an advantageous resistance to corrosion.

### FIELD OF THE INVENTION

The invention relates to aluminum alloy products designed to be used as elements of vacuum chambers, particularly for the manufacture of integrated electronic circuits containing semiconductors, flat display screens, photovoltaic panels and their method of manufacture.

### BACKGROUND OF RELATED ART

Vacuum chambers elements for the manufacture of integrated electronic circuits using semiconductors, flat display screens and solar panels, may typically be obtained from plates of aluminum.

Vacuum chamber elements are elements for the manufacture of vacuum chamber structures and the internal components of the vacuum chamber, such as vacuum chamber bodies, valve bodies, flanges, connecting elements, sealing elements, pass through, diffusers and electrodes. They are in particular obtained by machining and surface treatment of aluminum alloy plates.

To obtain satisfactory vacuum chamber elements, aluminum alloy plates must have certain properties.

The plates must first of all have satisfactory mechanical characteristics to allow machine production of parts of the required dimensions and rigidity in order to be able to obtain a vacuum generally at least of the level of the average vacuum (10⁻³-10⁻⁵ Torr) without bending. The required ultimate tensile strength (Rₘ) is therefore generally at least 260 MPa and even more if possible. Additionally, for them to be machined, the plates to be bulk machined must have homogeneous properties throughout their thickness and have a low density of stored elastic energy from residual stresses.

The level of porosity of the plates must in addition be sufficiently low to obtain a high vacuum (10⁻⁶-10⁻⁸ Torr) if required. In addition, the gases used in vacuum chambers are frequently very corrosive and in order to avoid the risks of pollution of the silicon wafers or liquid crystal devices by particles or substances coming from the vacuum chamber elements and/or frequent replacement of these elements, it is important to protect the surfaces of the vacuum chamber elements. Aluminum proves to be an advantageous material from this point of view because it is possible to carry out surface treatment producing a hard anodized oxide coating, resistant to reactive gases. This surface treatment comprises an anodizing step and the oxide layer obtained is generally called an anodic layer. In the context of the invention, “corrosion resistance” is taken more specifically to mean the resistance of anodized aluminum to corrosive gases used in vacuum chambers and to the corresponding tests. However, the protection provided by the anodic layer is affected by many factors in particular related to the microstructure of the plate (grain size and shape, phase precipitation, porosity) and it is always desirable to improve this parameter. Corrosion resistance can be evaluated by the test known as a “bubble test” which involves measuring the time of occurrence of hydrogen bubbles on the surface of the anodized product upon contact with a dilute solution of hydrochloric acid. Times known in prior art are from tens of minutes to several hours.

To improve the vacuum chamber elements, one can improve the aluminum plates and/or the surface treatment performed.

U.S. Pat. No. 6,713,188 (Applied Materials Inc.) describes an alloy suitable for the manufacture of chambers for the manufacture of semiconductors composed as follows (as a percentage by weight): 0.4-0.8; Cu: 0.15-0.30; Fe: 0.001-0.20; Mn 0.001-0.14; Zn 0.001-0.15; Cr: 0.04-0.28; Ti 0.001-≦0.06; Mg: 0.8-1.2. The parts are obtained by extrusion or machining to reach the required shape. The composition makes it possible to check the size of the impurity particles which improves the performance of the anodic layer.

U.S. Pat. No. 7,033,447 (Applied Materials Inc.) claims an alloy suitable for the manufacture of chambers for the manufacture of semiconductors composed as follows (as a percentage by weight) Mg: 3.5-4.0; Cu: 0.02-0.07; Mn: 0.005-0.015; Zn 0.08-0.16; Cr 0.02-0.07; Ti: 0-0.02; Si<0.03; Fe<0.03. The parts are anodized in a solution comprising 10% to 20% by weight of sulfuric acid, and 0.5 to 3% by weight of oxalic acid at a temperature of 7-21° C. The best result obtained with the bubble test is 20 hours.

U.S. Pat. No. 6,686,053 (Kobe) claims an alloy having an improved resistance to corrosion, wherein the anodic oxide comprises a barrier layer and a porous layer and wherein at least a portion of the layer is altered to boehmite and/or pseudoboehmite. The best result obtained with the test bubble is of the order of 10 hours.

US patent application 2009/0050485 (Kobe Steel, Ltd.) describes an alloy of composed as follows (as a percentage by weight): 0.1-2.0, Si: 0.1-2.0, Mn: 0.1-2.0; Fe, Cr, and Cu≦0.03, anodized so that the hardness of the anode oxide coating varies throughout the thickness. The very low iron, chromium and copper content lead to a high excess cost for the metal used.

US patent application 2010/0018617 (Kobe Steel, Ltd.) describes an alloy composed as follows (as a percentage by weight) Mg: 0.1-2.0, Si: 0.1-2.0, Mn: 0.1-2.0; Fe, Cr, and Cu≦0.03, the alloy being homogenized at a temperature of over 550° C. up to 600° C. or less.

US patent application. 2001/019777 and JP2001 220637 (Kobe Steel) describe an alloy for chambers comprising (as percentage by weight) Si: 0.1-2.0. Mg: 0.1-3.5, Cu: 0.02-4.0 and impurities, the Cr content being less than 0.04%. These documents disclose products obtained by performing a hot rolling step before the solution heat treatment.

The international application WO2011/89337 (Constellium) describes a process for manufacturing cast unlaminated products suitable for the fabrication of vacuum chamber elements, composed as follows (as a percentage by weight), Si: 0.5-1.5; Mg: 0.5-1.5; Fe<0.3; Cu<0.2; Mn<0.8; Cr<0.10; Ti<0.15.

U.S. Pat. No. 6,066,392 (Kobe Steel) discloses an aluminum material having an anodic oxidation film with improved corrosion resistance, wherein cracks are not generated even in high-temperature thermal cycles and in corrosive environments.

U.S. Pat. No. 6,027,629 (Kobe Steel) describes an improved method of surface treatment for vacuum chamber elements wherein the pore diameter of the anodic oxide film is variable within the thickness thereof.

U.S. Pat. No. 7,005,194 (Kobe Steel) describes an improved method of surface treatment for vacuum chamber elements wherein the anodized film is composed of a porous layer and a nonporous layer whose structure is at least partly of boehmite or pseudoboehmite.

U.S. Pat. No. 3,524,799 (Reynolds) describes a hard dense anodic coating formed on an aluminium surface by anodizing with an aqueous electrolyte containing a mineral acid such as sulfuric acid, a polyhydric alcohol of 3 to 6 carbon atoms, an organic carboxylic acid and an alkali salt of a titanic complex of a hydroxyaliphatic carboxylic acid suitable for aluminium surfaces of space vehicles for which a white and bright coating is needed.

These documents do not mention the problem of improving the homogeneity of the properties within the thickness of the vacuum chamber elements. In addition, producing certain vacuum chamber elements requires the use of thick plates, typically at least 60 mm thick, for which it is more difficult to achieve satisfactory corrosion resistance.

There is a need for further improved vacuum chamber elements, especially in terms of corrosion resistance, homogeneity of properties throughout the thickness and machinabilty. Corrosion resistance and mechanical properties must be improved throughout the entire thickness of the aluminum alloy plate, in particular to facilitate machining and to allow any part of the plate to come into contact with the atmosphere of the chamber. There is also a need for improved thick aluminum alloy plates for the production of vacuum chamber components.

### SUBJECT OF THE INVENTION

The first subject of the invention is a vacuum chamber obtained by machining and surface treatment of a plate of thickness at least equal to 10 mm of aluminum alloy, composed as follows, in weight %, Si: 0.4-0.7; Mg: 0.4-0.7; Ti: 0.01-<0.15, Fe<0.25; Cu<0.04; Mn<0.4; Cr: 0.01-<0.1; Zn<0.04; other elements <0.05 each and <0.15 in total, the rest aluminum.

Another subject of the invention is a manufacturing process for a vacuum chamber element wherein, successively,

a. a rolling slab made of an aluminum alloy according to the invention is cast,
b. optionally, said rolling slab is homogenized,
c. said rolling slab is rolled at a temperature above 450° C. to obtain a plate having a thickness at least equal to 10 mm,
d. solution heat treatment of said plate is carried out, and it is quenched,
e. after solution heat treatment and quenching, said plate is stress-relieved by controlled stretching with permanent elongation of 1 to 5%,
f. the stretched plate then undergoes aging,
g. the aged plate is machined into a vacuum chamber element,
h. the vacuum chamber element so obtained undergoes surface treatment, preferably including anodizing at a temperature of between 10 and 30° C. with a solution comprising 100 to 300 g/l of sulfuric acid and 10 to 30 g/l of oxalic acid and 5 to 30 g/l of at least one polyol.

Still another subject of the invention is a manufacturing process for a vacuum chamber element wherein successively
a plate with a thickness of at least 10 mm of aluminum alloy of series 5XXX or series 6XXX is provided
said plate is machined to a vacuum chamber element
   said element is degreased and/or pickled
   it is anodized at a temperature of between 10 and 30° C. with a solution comprising 100 to 300 g/l of sulfuric acid and 10 to 30 g/l of oxalic acid and 5 to 30 g/l of at least one polyol,
   optionally the anodized product is hydrated in deionized water at a temperature of at least 98° C. preferably for a period of at least about 1 h.

The patent or application file contains at least one drawing executed in color. Copies of this patent or patent application publication with the color drawing(s) will be provided by the Office upon request and payment of the necessary fee.

### DESCRIPTION OF THE FIGURES

FIG. 1 shows the granular structure of the products A to C obtained in example 1 on sections L/ST after Barker etching on the surface, at a quarter-thickness and at mid-thickness.

FIG. 2 shows the stress profile in the thickness for direction L for the products obtained in example 1.

FIG. 3 shows the granular structure of the product D obtained in example 1 on sections L/ST after Barker etching on the surface, at a quarter-thickness and at mid-thickness.

### DETAILED DESCRIPTION OF THE INVENTION

The designation of alloys is compliant with the rules of The Aluminum Association (AA), known to those skilled in the art. The definitions of metallurgical tempers are indicated in European standard EN515. Unless otherwise stated, the definitions of standard EN 12258-1 apply.

Unless otherwise stated, the static mechanical characteristics, in other words the ultimate tensile strength Rm, the conventional yield stress at 0.2% of elongation Rp 0.2 and elongation at break A %, are determined by a tensile test according to standard ISO 6892-1, sampling and test direction being defined by standard EN 485-1. Hardness is measured according to standard EN ISO 6506. Grain sizes are measured in accordance with standard ASTM E112. The electric breakdown voltage is measured according to EN ISO 2376: 2010.

The present inventors have found that vacuum chamber elements having very advantageous properties, especially in terms of corrosion resistance, consistency of properties and machinability, are obtained for an aluminum alloy of the specific 6xxx series. A manufacturing process for a vacuum chamber element comprising an advantageous surface treatment method for those products and significantly improving homogeneity of properties throughout the thickness and resistance to corrosion of vacuum chamber elements has also been invented.

Particularly advantageous properties are obtained by combining the alloy according to the invention and the advantageous surface treatment method.

The composition of the aluminum alloy plates to obtain the vacuum chamber elements according to the invention is as follows (as a percentage by weight), Si: 0.4-0.7; Mg: 0.4-0.7; Ti: 0.01-<0.15, Fe<0.25; Cu<0.04; Mn<0.4; Cr: 0.01-<0.1; Zn<0.04; other elements <0.05 each and <0.15 in total, the rest aluminum.

Control of the maximum content of certain elements is important because these elements can, if present at levels above those recommended, cause the properties of the anodic oxide layer to deteriorate and/or contaminate the products manufactured in the vacuum chambers. The manganese content is therefore less than 0.4% by weight, preferably less than 0.04% by weight and most preferably less than 0.02% by weight. The copper content is less than 0.04% by weight, preferably less than 0.02% by weight and preferably less than 0.01% by weight. The zinc content is less than 0.04% by weight, preferably less than 0.02% by weight and preferably less than 0.001% by weight.

An excessive amount of chromium may also have an adverse effect on the properties of the anodic oxide layer. The chromium content is therefore less than 0.1% by weight. However, the addition of a small amount of chromium has a positive effect on the granular structure, so that the minimum chromium content is 0.01 wt. %. In an advantageous embodiment of the invention, the chromium content is from 0.01 to 0.04% by weight and preferably from 0.01 to 0.03% by weight.

An excessive amount of iron may also have an adverse effect on the properties of the anodic oxide layer. The iron content is therefore less than 0.25% by weight. However, the addition of a small amount of iron has a positive effect on the granular structure. In an advantageous embodiment of the invention, the iron content is from 0.05 to 0.2% by weight and preferably from 0.1 to 0.2% by weight.

An excessive amount of titanium may also have an adverse effect on the properties of the anodic oxide layer. The titanium content is therefore less than 0.15% by weight. However, the addition of a small amount of titanium has a positive effect on the granular structure so that the minimum chromium content is 0.01 wt. %. In an advantageous embodiment of the invention, the titanium content is from 0.01 to 0.1% by weight and preferably from 0.01 to 0.05% by weight. Advantageously the titanium content is at least 0.02 wt. % and preferentially 0.03 wt. %. Simultaneous addition of chromium and titanium is advantageous because it enables particularly to improve the grain structure and in particular to decrease the grains anisotropy index.

Magnesium and silicon are the major additive elements in the alloy products according to the invention. Their content has been accurately selected so as to obtain the adequate mechanical properties, especially tensile strength in the direction LT of at least 260 MPa and/or a yield strength in the direction LT of at least 200 MPa and also a homogeneous granular structure throughout the thickness. The silicon content lies between 0.4 and 0.7% by weight and preferably between 0.5 and 0.6% by weight. The magnesium content lies between 0.4 and 0.7% by weight and preferably between 0.5 and 0.6% by weight.

The aluminum alloy plates according to the invention have a thickness of at least 10 mm Typically, the aluminum alloy plates according to the invention have a thickness of between 10 and 60 mm. However, the present inventors have found that f aluminum alloy plates according to the invention are advantageous when a thickness of at least 60 mm is desired.

The plates that make it possible to obtain the vacuum chamber elements according to the invention are obtained by a process wherein
a. an rolling slab of an alloy according to the invention is cast,
b. optionally, said rolling slab is homogenized,
c. said rolling slab is rolled at a temperature above 450° C. to obtain a plate having a thickness at least equal to 10 mm,
d. solution heat treatment of said plate is carried out, and it is quenched,
e. after solution heat treatment, said plate is stress-relieved by controlled stretching with permanent elongation of 1 to 5%,
f. the stretched plate undergoes aging,

Homogenization is advantageous, and is preferably carried out at a temperature between 540 and 600° C. Preferably, homogenization time is at least 4 hours.

When homogenization is carried out, the plate can be cooled after homogenization and then reheated before hot rolling or rolled directly without intermediate cooling. The hot rolling conditions are important to obtain the desired microstructure, in particular to improve the corrosion resistance of the products. In particular, the rolling slab is maintained at a temperature above 450° C. throughout the hot rolling process. Preferably, the metal temperature is at least 480° C. during hot rolling. The plates according to the invention are rolled to a thickness of at least 10 mm. The homogeneity of the microstructure throughout the thickness, the equiaxed nature of the grains and the microstructure favorable for improving the corrosion resistance of the products according to the invention is particularly advantageous; this is favored by the choice of a high hot rolling temperature in combination with a composition having an optimal amount of anti-recrystallising elements.

Then solution heat treatment is performed on the plate and it is quenched. Quenching can be performed in particular by spraying or immersion. The solution heat treatment is preferably performed at a temperature between 540 and 600° C. Preferably, the solution heat treatment time is at least 15 min, the length being adjusted according to the thickness of the products.

The plate having undergone solution heat treatment is then stress relieved by controlled stretching with a permanent elongation of 1 to 5%.

The stretched plate then undergoes aging. The aging temperature is advantageously between 150 and 190° C. Aging time is typically between 5 and 30 hours. Preferably aging is performed at the peak to achieve maximum yield strength and/or a T651 temper.

The plate thus obtained has a very homogeneous grain size throughout its thickness. Preferably the variation in the thickness of the average linear intercept length in the plane L/ST, named l̅_{l(90°)} according to ASTM E112, of said plate is less than 30% and preferably less than 20% and even advantageously less than 15%. The variation in grain size is calculated as the difference between the maximum value and the minimum value at ½ thickness, ¼thickness and surface, and dividing by the average of the values at ½ thickness, ¼thickness and surface. The homogeneity of the grain structure, which comes from the combination of the selected composition and the transformation schedule, is particularly advantageous because the properties of the vacuum chamber element obtained after machining are very homogeneous in all respects. The granular structure of the plates according to the invention is more isotropic than that of plates of prior art, regardless of the position in the thickness which is advantageous for corrosion resistance properties, homogeneity of properties throughout the thickness and machinabilty for manufacturing vacuum chamber elements. In particular, at half-thickness the anisotropy index AIₗ= l̅_{l (90°)}/ l̅_{l(90°)} measured according to ASTM E112 is less than 3.

The plate thus obtained is particularly suitable for machining. The density of stored elastic energy Wₜₒₜ, whose measurement is described in example 1, in a plate according to the invention, whose thickness is between 10 and 60 mm is therefore preferably less than 0.04 kJ/m³.

A vacuum chamber element is obtained by machining and surface treatment of a plate of thickness at least equal to 10 mm of aluminum alloy according to the invention.

The surface treatment comprises an anodizing treatment to obtain an anodic layer having a thickness typically between 20 and 80 μm.

The surface treatment preferably includes, before anodizing, degreasing and/or pickling with known products, typically alkaline products. Degreasing and/or pickling may include a neutralization operation particularly in the event of alkaline pickling, typically with an acid such as nitric acid, and/or at least one rinsing step.

Anodizing is carried out using an acid solution. It is advantageous for the surface treatment to include hydration after anodizing (also called “sealing”) of the anodic layer obtained.

Due to the homogeneous structure throughout the thickness of the products according to the invention, the variation between the time of appearance of hydrogen bubbles in a 5% hydrochloric acid solution (“bubble test”) between ½ thickness and surface is advantageously less than 20%, particularly when the plate thickness is between 10 and 60 mm.

The present inventors further found that the manufacturing method for vacuum chamber elements wherein successively
a plate with a thickness of at least 10 mm of aluminum alloy of series 5XXX or series 6XXX is provided
said plate is machined to a vacuum chamber element
said element is degreased and/or pickled
it is anodized at a temperature of between 10 and 30° C. with a solution comprising 100 to 300 g/l of sulfuric acid and 10 to 30 g/l of oxalic acid and 5 to 30 g/l of at least one polyol,
optionally the anodized product is hydrated in deionized water at a temperature of at least 98° C. preferably for a period of at least about 1 h is advantageous.

In particular those advantageous anodizing conditions make it possible to achieve, both at the surface and at mid-thickness, particularly noteworthy hydrogen bubble appearance times in the bubble test for 5XXX series and 6xxx series alloys, especially for the 6XXX series alloys. These advantageous anodizing conditions give outstanding results for alloy products according to the invention.

So, in the manufacturing method for vacuum chamber elements according to the invention, an advantageous surface treatment method comprising anodizing at a temperature between 10 and 30° C. with an aqueous solution comprising 100 to 300 g/l of sulfuric acid and 10 to 30 g/l of oxalic acid and 5 to 30 g/l of at least one polyol is carried out. Preferably, the aqueous solution used for the anodizing of this advantageous surface treatment method does not contain any titanium salt. The present inventors in particular found that anodizing performed at low temperature, typically between 0 and 5° C., does not give as high a corrosion resistance as that obtained at a temperature of between 10 and 30° C. The presence of at least one polyol in the anodizing solution also contributes to improved corrosion resistance of the anodic layers. Ethylene glycol, propylene glycol or preferably glycerol are preferred polyols. Anodizing is preferably carried out with a current density of between 1 and 5 A/dm². Anodizing time is determined so as to achieve the desired anodic layer thickness.

After anodizing, it is advantageous to perform a hydration step (also called sealing) on the anodic layer. Preferably, hydration is carried out in deionized water at a temperature of at least 98° C. preferably for a period of at least about 1 hour. The present inventors found that it is particularly advantageous to perform hydration after anodizing in two steps in deionized water, the first step being for a period of at least 10 minutes at a temperature of 20 to 70° C. and the second step of a duration of at least about 1 hour at a temperature of at least 98° C. Advantageously an anti-smutting triazine derivative agent such as -SH1 Anodal® is added to the deionized water used in the second hydration step.

Vacuum chamber elements treated with the advantageous surface treatment method and obtained from plates having a thickness of between 10 and 60 mm easily reach a hydrogen bubble appearance time in a solution of 5% hydrochloric acid (“bubble test”) of at least about 1500 minutes and even at least about 2000 minutes, at least for the portion corresponding to the surface of the plate. Vacuum chambers elements obtained from an alloy plate according to the invention, with thickness between 10 and 60 mm and with the advantageous surface treatment method, have at mid-thickness of the plate a hydrogen bubble appearance time in a 5% hydrochloric acid solution greater than 1800 minutes, or 30 hours. Vacuum chambers elements obtained from an alloy plate according to the invention, with thickness greater than 60 mm and with the advantageous surface treatment method, have on the surface of the plate a hydrogen bubble appearance time in a 5% hydrochloric acid solution of at least 180 minutes, and preferably at least 300 minutes

The use of vacuum chamber elements according to the invention in vacuum chambers is particularly advantageous because their properties are very homogeneous and in addition, especially for elements anodized with the advantageous surface treatment process, corrosion resistance is high, which prevents contamination of the products manufactured in the chambers such as, for example, microprocessors or faceplates for flat screens.

### EXAMPLES

### Example 1

In this example 6xxx alloy plates of thickness 20 mm or 35 mm were prepared.

Slabs were cast: their composition is given in Table 1

TABLE 1
Composition of alloys (% by weight)

| Alloy | Si | Fe | Cu | Mn | Mg | Cr | Ti | Zn |
|---|---|---|---|---|---|---|---|---|
| A (Invention) | 0.5 | 0.12 | <0.01 | <0.01 | 0.5 | 0.02 | 0.04 | <0.01 |
| B (Reference) | 0.6 | 0.15 | 0.16 | 0.01 | 1.1 | 0.06 | 0.02 | <0.01 |
| C (Reference) | 0.6 | 0.12 | 0.18 | <0.01 | 1.0 | 0.19 | 0.02 | <0.01 |
| D (Reference) | 0.6 | 0.15 | <0.01 | 0.3 | 0.7 | <0.01 | 0.01 | <0.01 |

The slabs were homogenized at a temperature higher than 540° C. (A to C) or 575° C. (D), hot rolled to a thickness of 35 mm (A to C) or 20 mm (D) and then given solution heat treatment, quenched and stretched. The plates obtained underwent suitable aging to reach a T651 temper.

Mechanical properties in the direction LT were measured at mid-thickness and are given in Table 2

TABLE 2
Mechanical properties at mid-thickness in the direction LT

| | Rp0.2 | Rm | |
|---|---|---|---|
| Alloy | (MPa) | (MPa) | A (%) |
| A (Invention) | 215 | 275 | 15 |
| B (Reference) | 306 | 342 | 12 |
| C (Reference) | 300 | 332 | 14 |
| D (Reference) | 249 | 274 | 13 |

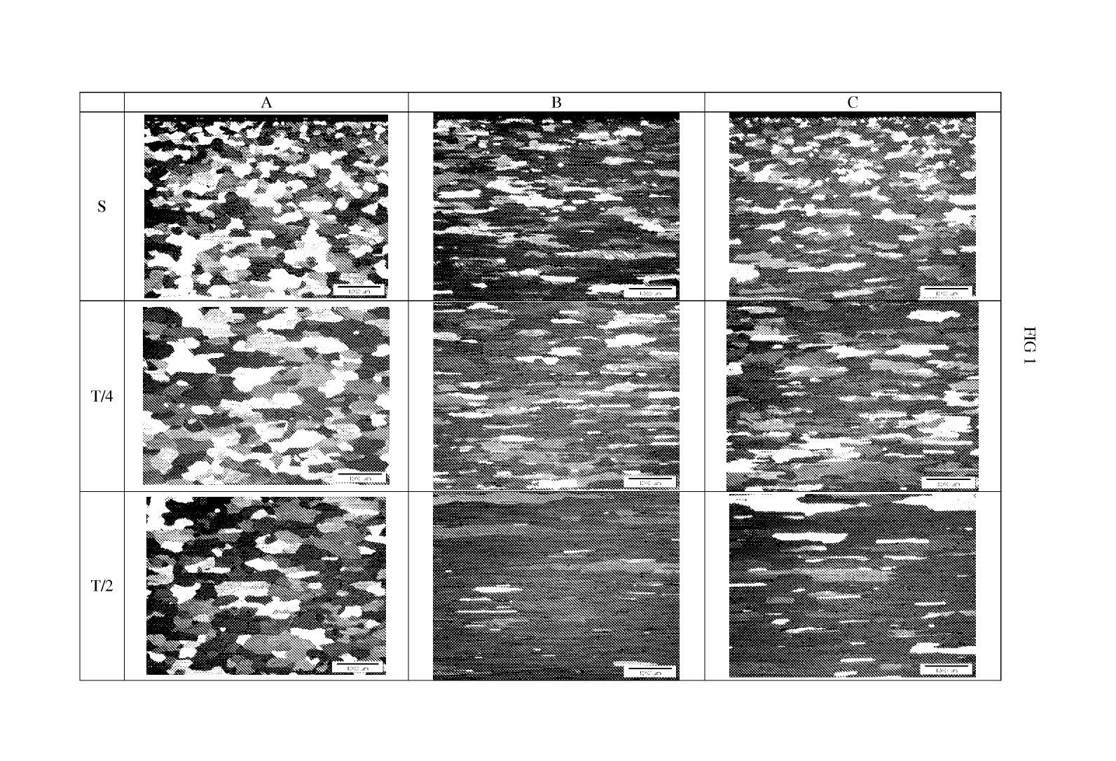

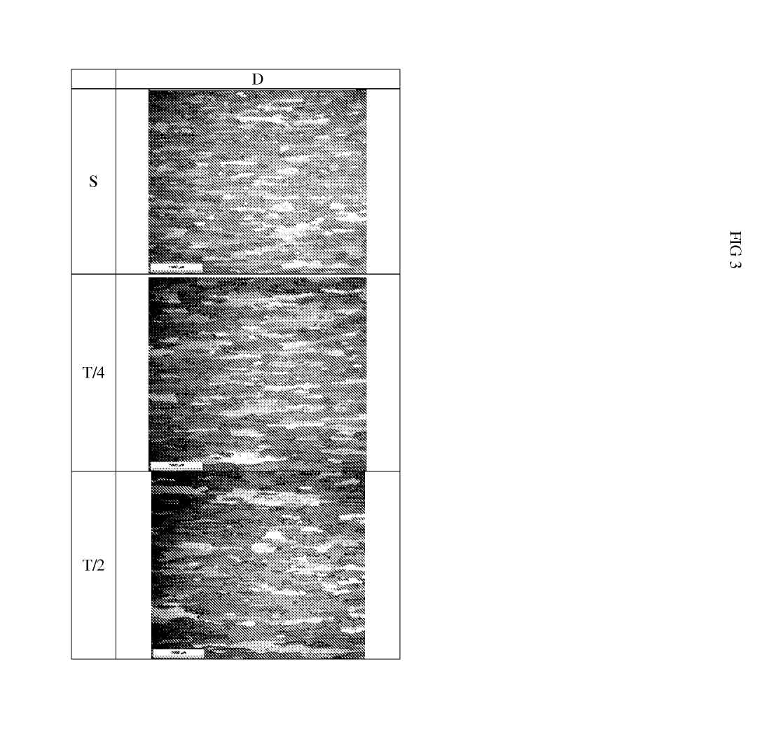

The granular structure of the various products obtained was observed on sections L/ST by optical microscopy after Barker etching, on the surface and at quarter and mid-thickness. Micrographs are shown in FIGS. 1 and 3.

The average grain sizes measured in the plane L/ST using the intercept method of the standard (ASTM E112-96 §16.3) are presented in Table 3. The average length of linear intercept is given in the longitudinal direction l̅_{l(0°)} and the transverse direction l̅_{l(90°)}. An average value in plane L/ST is calculated: l̅=( l̅_{l(0°)}· l̅_{l(0°)}· l̅_{l(90°)})^{1/2}. The anisotropy index AIₗ= l̅_{l(90°)}/ l̅_{l(90°)} is also calculated. The variation in the thickness of l̅_{l(90°)}, Δ l̅_{l(90°)} is also calculated using the formula:

Δ l̅_{l(90°)}=(max( l̅_{l(90°)}(S,½Th,¼Th))−min( l̅_{l(90°)}(S,½Th,¼Th)))/av( l̅_{l(90°)}(S,½Th,¼Th))

where S means Surface, ½ Th means mid-thickness and ¼ Th means quarter thickness.

TABLE 3
grain size in the plane L-ST (μm)

| | | l̅_{l(90°)} | l̅_{l(0°)}. | l̅ | AIₗ | Δ |
|---|---|---|---|---|---|---|
| Alloy | Position | μm | μm | μm | (L/ST) | l̅_{l(90°)} |
| A | Surface | 171 | 293 | 224 | 1.7 | 11% |
| | ¼ thickness | 188 | 390 | 271 | 2.1 | |
| | ½ thickness | 190 | 421 | 283 | 2.2 | |
| B | Surface | 106 | 351 | 193 | 3.3 | 45% |
| | ¼ thickness | 124 | 438 | 233 | 3.5 | |
| | ½ thickness | 166 | 1500 | 499 | 9.0 | |
| C | Surface | 103 | 618 | 252 | 6.0 | 53% |
| | ¼ thickness | 125 | 641 | 284 | 5.1 | |
| | ½ thickness | 175 | >2000 | 591 | >11 | |
| D | Surface | 99 | 284 | 168 | 2.9 | 10% |
| | ¼ thickness | 95 | 364 | 186 | 3.8 | |
| | ½ thickness | 105 | 324 | 184 | 3.1 | |

It can be seen that the product according to the invention has a more isotropic and more homogeneous grain size throughout the thickness than that of other alloys. These characteristics are very favorable for homogeneity of machining and of the properties after machining Sample D for which no chromium addition was done exhibit in particular an anisotropy index higher than sample A.

Residual stresses in the thickness were evaluated using the method of step-by-step machining of rectangular bars taken from the full thickness in directions L and LT, described for example in the publication “Development of New Alloy for Distortion Free Machined Aluminum Aircraft Components”, F. Heymes, B. Commet, B. Dubost, P. Lassince, P. Lequeu, G M. Raynaud, in 1^{st} International Non-Ferrous Processing & Technology Conference, 10-12 Mar. 1997—Adams's Mark Hotel, St Louis, Mo.

This method applies mainly to slabs whose length and width are significantly higher than their thickness and for which the residual stress state can reasonably be considered to be biaxial with its two main components in directions L and T (i.e. no residual stress in direction S) and such that the level of residual stress varies only in direction S. This method is based on measuring the deformation of two rectangular bars of full thickness which are cut from the slab along directions L and LT. These bars are machined downwards in the S direction step by step, and at each step the curvature is measured, as well as the thickness of the machined bar.

The bar width was 30 mm. The bar must be long enough to avoid any edge effect on the measurements. A length of 400 mm was used.

The measurements were performed after each machining pass.

After each machining pass, the bar is removed from the vice, and a stabilization time is observed before measuring deformation, so as to obtain a uniform temperature in the bar after machining.

At each step i, the thickness h(i) of each bar and the curvature f(i) of each bar are collected. These data are used to calculate the residual stress profile in the bar, corresponding to the stress σ(i)_{L} and to the stress σ(i)_{LT} as an average in the layer removed during step i, given by the following formulae, wherein E is Young's modulus, lf is the length of the supports used to measure the curvature and v is Poisson's ratio:

from i=1 to N−1

$${u ( i )}_{L} = - E \frac{4}{3} \frac{E}{{lf}^{2}} [ {f ( i + 1 )}_{L} - {f ( i )}_{L} ] \frac{{h}^{3} ( i + 1 )}{h ( i ) h ( i ) - ( h ( i + 1 ) )} - {S ( i )}_{L}$$

$${S ( i )}_{L} = \frac{4 E}{{lf}^{2}} {\sum }_{k = 1}^{i - 1} [ f {( i + 1 )}_{L} - {f ( i )}_{L} ] [ - ( h ( i ) + ( h ( i + 1 ) ) + \frac{h ( k + 1 ) ( 3 h ( k ) - h ( k + 1 ) )}{3 h ( k )} ] \\ {σ ( i )}_{L} = \frac{{u ( i )}_{L} + {vu ( i )}_{LT}}{1 - {v}^{2 }} \\ {σ ( i )}_{LT} = \frac{{u ( i )}_{LT} + {vu ( i )}_{L}}{1 - {v}^{2}}$$

Finally, the density of elastic energy stored in the bar Wₜₒₜ can be calculated from the residual stress values using the following formulae:

Wₜₒₜ=W_{L}+W_{LT}

where

$${W}_{L} ( kJ \text{/} {m}^{3} ) = \frac{500}{Eth} {\sum }_{i = 1}^{N - 1} {σ}_{L} ( i ) [ {σ}_{L} ( i ) - v {σ}_{LT} ( i ) ] dh ( i )$$

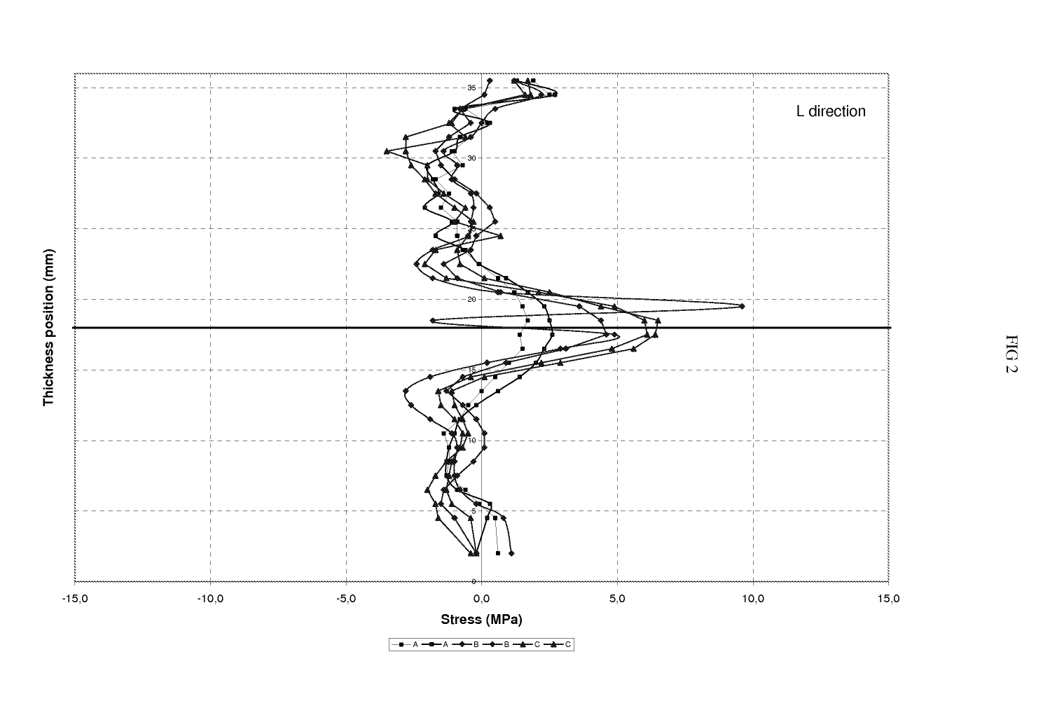

The stress profile throughout the thickness for direction L is given in FIG. 2.

The total energy measured Wₜₒₜ was 0.03 kJ/m³ for sample A, 0.04 kJ/m³ for sample B and 0.05 kJ/m³ for sample C. Sample A according to the invention thus has a lower level of internal stresses which is advantageous for machining parts.

Two anodizing treatments were used to evaluate the properties of the products obtained. The products were characterized in plane L−LT on the surface (or after slight machining) or after machining to mid-thickness.

In treatment I the product was degreased and pickled with an alkaline solution, then neutralized with a nitric acid solution prior to undergoing anodizing at a temperature between 0 and 5° C. in a sulfuric-oxalic bath (sulfuric acid 180 g/l+oxalic acid 14 g/l). After anodizing, a hydration treatment of the anodic layer was performed in two steps: 20 minutes at 50° C. in deionized water and then 80 minutes in boiling deionized water in the presence of an anti-smutting triazine derivative additive, Anodal-SH1 ®. The anodic layer obtained had a thickness of about 40 μm.

In treatment II the product was degreased and pickled with an alkaline solution, then neutralized with a nitric acid solution prior to undergoing anodizing at a temperature of about 20° C. in a sulfuric-oxalic bath (sulfuric acid 160 g/l+oxalic acid 20 g/l+15 g/l of glycerol). After anodizing, a hydration treatment of the anodic layer was performed in two steps: 20 minutes at 50° C. in deionized water and then 80 minutes in boiling deionized water in the presence of an anti-smutting triazine derivative additive, Anodal-SH1 ®. The anodic layer obtained had a thickness of about 35 or 50 μm.

The anodic layers were characterized by the following tests.

The electric breakdown voltage characterizes the voltage at which the first electric current flows through the anodic layer. The method of measurement is described in EN ISO 2376:2010. Values are given in absolute value after direct current (DC) measurement.

The “bubble test” is a corrosion test for characterizing the quality of the anodic layer by measuring the time it takes for the first bubbles to appear in a solution of hydrochloric acid. A flat surface 20 mm in diameter of the sample is put into contact at room temperature with a solution containing 5% by weight of HCl. The characteristic time is the time from which a continuous stream of bubbles of gas from at least one discrete point of the surface of the anodized aluminum is visible.

The results measured on the surface and at mid-thickness are presented in Table 4.

TABLE 4
Characterization of the products after anodizing

| | | | Thickness of | | |
|---|---|---|---|---|---|
| | | | layer | | Breakdown |
| | | | targeted | Bubble | voltage |
| Position | Anodizing | Alloy | (μm) | test (min) | (KV) |
| Surface | Type I | A | 40 | 50 | 1.5 |
| | | B | 40 | 25 | 2.2 |
| | | C | 40 | 180 | 2.6 |
| | Type II | A | 35 | 2400 | 2.0 |
| | | A | 50 | 3000 | 2.3 |
| | | B | 35 | 1980 | 3.0 |
| | | C | 35 | 2700 | 2.8 |
| Mid- | Type I | A | 40 | 50 | 1.8 |
| thickness | | B | 40 | 135 | 2.0 |
| | | C | 40 | 75 | 2.3 |
| | Type II | A | 35 | 2900 | 2.1 |
| | | A | 50 | 3000 | 2.2 |
| | | B | 35 | 720 | 2.8 |
| | | C | 35 | 1700 | 2.8 |

Irrespective of the surface treatment, the product according to the invention has very homogeneous properties between surface and mid-thickness. Times in the bubble test are particularly high with anodizing according to the invention.

### Example 2

In this example, the effect of the presence of glycerol in the anodizing solution is studied. In the type I treatment described above, for certain tests, 15 g/l of glycerol was added, and in the type II treatment, glycerol was not added to certain tests.

The results are given in Table 5.

TABLE 5
Effect of the presence of glycerol in the anodizing solution

| | | | | | | Break- |
|---|---|---|---|---|---|---|
| | | | | Layer | Bubble | down |
| Anod- | | Al- | Posi- | thickness | test | voltage |
| izing | | loy | tion | (μm) | (min) | (KV) |
| Type I | without | A | Surface | 35-40 | 50 | 1.5 |
| | glycerol | A | Surface | 64 | 94 | 2.6 |
| | Glycerol 15 g/l | A | Surface | 52 | 270 | 1.7 |
| Type II | without | A | Surface | 35 | 1380 | 1.3 |
| | glycerol | A | Surface | 58 | 865 | 2.2 |
| | Glycerol 15 g/l | A | Surface | 35 | 2400 | 2.0 |
| | | A | Surface | 48 | 3000 | 2.2 |

the presence of glycerol during anodizing very significantly improves the duration obtained during the bubble test, in particular for type II anodizing.

### Example 3

In this example, the corrosion resistance of thick alloy plates according to the invention was evaluated in comparison with a reference 6061 alloy plate.

A 102 mm thick A alloy plate was prepared by the method described in Example 1. A reference 6061 alloy plate was also prepared to a thickness of 100 mm. The plates obtained were then processed using the type II surface treatment described in Example 1. The products thus obtained were characterized by the bubble test described in Example 1. The time to hydrogen bubble appearance was 60 min for the 6061 alloy plates, whereas it was 320 min for the A alloy plates.

1. Vacuum chamber element obtained by machining and surface treatment of a plate of thickness at least equal to 10 mm of an aluminum alloy, composed as follows, in weight %, Si: 0.4-0.7; Mg: 0.4-0.7; Ti: 0.01-<0.15, Fe<0.25; Cu<0.04; Mn<0.4; Cr: 0.01-<0.1; Zn<0.04; other elements <0.05 each and <0.15 in total, the rest aluminum.

2. Element according to claim 1 wherein the manganese content is lower than 0.04% by weight and optionally lower than 0.02% by weight

3. Element according to claim 1 wherein the chrome content is from 0.01 to 0.04% by weight and optionally from 0.01 to 0.03% by weight.

4. Element according to claim 1 wherein the iron content is from 0.05 to 0.2% by weight and optionally from 0.1 to 0.2% by weight.

5. Element according to claim 1 wherein the silicon content is from 0.5 to 0.6% by weight.

6. Element according to claim 1 wherein the magnesium content is from 0.5 to 0.6% by weight.

7. Element according to claim 1 wherein the copper content is lower than 0.02% by weight and optionally lower than 0.01% by weight.

8. Element according to claim 1 wherein the zinc content is lower than 0.02% by weight and optionally lower than 0.001% by weight.

9. Element according to claim 1 wherein the titanium content is from 0.01 to 0.1% by weight and optionally from 0.01 to 0.05% by weight.

10. Element according to claim 1 wherein said plate is such that the variation in the thickness of the average linear intercept length in the plane L/ST, named l̅_{l(90°)} according to standard ASTM E112, is less than 30% and optionally less than 20% and/or, at mid-thickness the anisotropy index AIₗ= l̅_{l (0°)}/ l̅_{l(90°)} measured according to standard ASTM E112 is less than 3.

11. Element according to claim 1 wherein said plate is such that a thickness thereof is between 10 and 60 mm and with a density of stored elastic energy Wₜₒₜ of less than 0.04 kJ/m³.

12. Element according to claim 1 wherein said surface treatment includes anodizing at a temperature between 10 and 30° C. with a solution comprising 100 to 300 g/l of sulfuric acid and 10 to 30 g/l of oxalic acid and 5 to 30 g/l of at least one polyol.

13. Element according to claim 12 wherein said plate is such that a thickness thereof is between 10 and 60 mm and has at mid-thickness a time to hydrogen bubble appearance in a 5% hydrochloric acid solution greater than 1800 min, or wherein said plate is such that a thickness thereof is greater than 60 mm and has on the surface a time to hydrogen bubble appearance in a 5% hydrochloric acid solution of at least 180 min.

14. Method of manufacturing a vacuum chamber element wherein successively
a. a rolling slab made of an aluminum alloy according to claim 1 is cast,
b. optionally, said rolling slab is homogenized,
c. said rolling slab is rolled at a temperature above 450° C. to obtain a plate having a thickness at least equal to 10 mm,
d. solution heat treatment of said plate is carried out, and it is quenched,
e. after solution heat treatment and quenching, said plate is stress-relieved by controlled stretching with permanent elongation of 1 to 5%,
f. the stretched plate then undergoes aging,
g. the aged plate is machined into a vacuum chamber element,
h. the vacuum chamber element so obtained undergoes surface treatment, optionally including anodizing at a temperature of between 10 and 30° C. with a solution comprising 100 to 300 g/l of sulfuric acid and 10 to 30 g/l of oxalic acid and 5 to 30 g/l of at least one polyol.

15. Manufacturing process for a vacuum chamber element wherein successively
a plate with a thickness of at least 10 mm of aluminum alloy of series 5XXX or series 6XXX is provided,
said plate is machined to a vacuum chamber element,
degreasing and/or pickling,
anodizing at a temperature of between 10 and 30° C. with a solution comprising 100 to 300 g/l of sulfuric acid and 10 to 30 g/l of oxalic acid and 5 to 30 g/l of at least one polyol,
optionally the anodized product is hydrated in deionized water at a temperature of at least 98° C. optionally for a period of at least about 1 h.

16. Method according to claim 15 wherein at least one polyol is selected from ethylene glycol, propylene glycol or glycerol.

17. Method according to claim 15 wherein anodizing is carried out with a current density of between 1 and 5 A/dm².

18. Method according to claim 15 wherein hydration is carried out in two steps, a first step of a duration of at least 10 min at a temperature of 20 to 70° C. and a second step of a duration of at least about 1 hour at a temperature of at least 98° C.

19. Method according to claim 15 wherein the anodic layer thickness obtained is between 20 and 80 μm.
